(19) United States
(12) Patent Application Publication
(10) Pub. No.: US 2016/0109527 A1
(43) Pub. Date: Apr. 21, 2016

(54) METHOD AND APPARATUS FOR DETERMINING A CHANGE IN RESISTANCE OF AN ENERGY STORAGE DEVICE AND VEHICLE

(71) Applicant: Volkswagen Aktiengesellschaft, Wolfsburg (DE)

(72) Inventors: Sascha Drenkelforth, Hannover (DE); Jorg Schleicher, Wittgensdorf (DE); Martin Mener, Chemnitz (DE); Michael Fiedler, Dresden (DE)

(73) Assignee: VOLKSWAGEN AKTIENGESELLSCHAFT, Wolfsburg (DE)

(21) Appl. No.: 14/882,516

(22) Filed: Oct. 14, 2015

(30) Foreign Application Priority Data
Oct. 15, 2014 (DE) 102014220913.7

(51) Int. Cl. G01R 31/36; B60L 11/18

(52) U.S. Cl. CPC G01R 31/3662; G01R 31/3648; B60L 11/1861

(57) ABSTRACT

An apparatus and a method for determining a change in resistance (ΔR₀) of an energy storage device, wherein a measurement voltage (Umeas) of the energy storage device is detected, wherein a model voltage (Umod) of the energy storage device is determined, wherein a deviation (Ue) between the model voltage (Umod) and the measurement voltage (Umeas) is determined, wherein a measurement current of the energy storage device is detected, wherein a change (Ud) in the deviation (Ue) over time is determined, wherein the change in resistance (ΔR₀) of the energy storage device is determined depending on the change (Ud) in the deviation (Ue) over time, and to a vehicle.

### FIELD OF THE INVENTION

The invention relates to a method and an apparatus for determining a change in resistance of an energy storage device, and to a vehicle.

### BACKGROUND OF THE INVENTION

Particularly in at least partly electrically operated vehicles and electric vehicles and hybrid vehicles, provision is made of energy storage devices that store the electrical energy required for driving operation and provide it for driving operation. The (internal) resistance of such an energy storage device constitutes an important characteristic value that serves in particular for determining a permissible power output. Via the change in resistance, the aging of the energy storage device can also be deduced, as a result of which e.g. a manner of operation can be adapted. Furthermore, the resistance is also required for modeling a dynamic behavior of the output voltage of the energy storage device.

DE 102 57 588 B3 describes a method for predicting a voltage of a battery, in particular of a vehicle battery. The method described makes it possible to predict a voltage dip before it actually occurs on account of loading. For this purpose, inter alia, the dynamic internal resistance is used and firstly a filtered battery voltage and a filtered battery current are ascertained. Ohmic voltage drop across the dynamic internal resistance is ascertained from a difference current between the filtered battery current and a predefined load current. A predicted battery voltage is calculated from the filtered battery voltage, minus the ohmic voltage drop and the filtered polarization voltage. However, the document does not describe a specific way of determining the dynamic internal resistance.

WO 2006/057468 A1 discloses a method for estimating values describing present operating conditions of a battery. The method comprises estimating a state of charge in a battery, wherein the state of charge is encompassed by an internal state variable. Furthermore, the method comprises estimating a state of health in a battery, wherein the state of health is encompassed by an internal parameter. The document describes a Kalman filter, wherein the resistance of a battery cell is contained as a state variable or parameter in the Kalman filter.

One disadvantage of such a Kalman filter-based estimation is that inaccuracies resulting from the model of an energy storage device used can lead to an erroneous determination of the internal resistance of the energy storage device. By way of example, inaccuracies in the determination of the state of charge (SOC), the temperature and/or the current can lead to inaccuracies in the determination of the resistance. For this reason, the resistance is not determined in critical operating states, for example at temperatures below 0° C., for states of charge between 0% to 10% and 90% to 100% and in the case of low current flows, for example current flows of less than 10 A.

DE 10 2011 017 113 A1 discloses determining the aging state of a rechargeable battery during operation, e.g. of a vehicle driven by an electric machine. A Kalman filter is used herein, too, namely a triply extended Kalman filter. In the method, a first Kalman filter is used to calculate the state of charge and the fast and slow overvoltages generated by the current, and a second Kalman filter is used to calculate the internal resistance, and a third Kalman filter is used to calculate the cell capacity.

DE 10 2012 010 487 A1 discloses a method for assessing an aging state of a battery using a family of characteristic curves.

### SUMMARY OF THE INVENTION

The technical problem addressed is that of providing a method and an apparatus for determining a change in resistance of an energy storage device and thus also a method and an apparatus for determining a resistance of the energy storage device which enable an accurate and reliable determination of the change in resistance and respectively of the resistance, in particular independently of model inaccuracies. Furthermore, the technical problem addressed is that of providing a corresponding vehicle.

The solution to the technical problem results from the subjects having the features of the independent claim(s). Further advantageous embodiments of the invention are evident from the dependent claims.

A method for determining a change in resistance of an energy storage device is proposed. The energy storage device can be in particular a battery cell or a traction battery, which can in turn comprise a plurality of battery cells. More particularly, the energy storage device can be an energy storage device in a vehicle. In this case, the energy storage device can store and provide energy for driving operation of the vehicle.

The method for determining a change in resistance can be part of a method for determining a resistance of the energy storage device. In this case, the resistance of the energy storage device can be determined from an initial resistance and the change in resistance, for example as a sum of the initial resistance and the change in resistance. In this case, the initial resistance can be previously known or predetermined. In particular, the initial resistance can be determined prior to a first start-up of the energy storage device, for example by means of suitable determining methods. Moreover, the initial resistance can be determined at the beginning of each driving cycle. By way of example, at the end of a driving cycle, a present resistance can be determined as a sum of the initial resistance determined at the beginning of the driving cycle and the change in resistance, wherein said present resistance is then stored and can serve as initial resistance at the beginning of a subsequent driving cycle.

In the proposed method, a measurement voltage of the energy storage device is detected. The measurement voltage can be an output voltage of the energy storage device. In this case, the detection can be carried out by means of a corresponding detection device, in particular by means of a voltage sensor. In this case, the term “detection” encompasses both the direct detection of the measurement voltage and a determination of the measurement voltage depending on a further, in particular directly, detected electrical variable.

Furthermore, a model voltage of the energy storage device is determined. The model voltage can model the output voltage of the energy storage device. The model voltage can denote e.g. an estimated output voltage of the energy storage device. The model voltage can be determined in particular depending on a preferably, but not necessarily, dynamic model of the energy storage device. The model can map for example a relationship between the model voltage and at least one operating parameter of the energy storage device. An operating parameter can be, inter alia, a state of charge (SOC), a temperature of the energy storage device and/or a current of the energy storage device. In this case, the current of the energy storage device can be a charging or discharging current.

The model can comprise at least one characteristic variable, which can also be referred to as model parameter. A characteristic variable can be, in particular, the resistance of the energy storage device. Consequently, the model voltage can be determined in particular depending on the resistance of the energy storage device. A further characteristic variable can be, for example, a time constant and/or a gain factor of a dynamic charging or discharging behavior.

Furthermore, a deviation between the model voltage and the measurement voltage is determined. The deviation can be determined for example as a difference between the model voltage and the measurement voltage.

Furthermore, a measurement current of the energy storage device can be detected. This can be carried out for example by means of a suitable detection device, in particular by means of a current sensor. In this case, the measurement current can denote a charging or discharging current of the energy storage device. In this case, it can be assumed, for example, that a charging current has a positive sign, a discharging current having a negative sign. The model voltage can be determined for example depending on the detected measurement current.

According to the invention, a change in the deviation over time is determined, wherein the change in resistance of the energy storage device is determined depending on the change in the deviation over time. Furthermore, a change in the measurement current over time can also be determined, wherein the change in resistance is additionally determined depending on the change in the measurement current over time. The change in the deviation over time can denote a quantitative value of the change over time.

Consequently, a method is described in which the change in resistance is not determined depending on the deviation between the model voltage and the measurement voltage, but rather depending on the change in said deviation over time. This means that an offset between the model voltage and the measurement voltage does not lead to a determination of an altered resistance if said offset is constant over time, in particular even during dynamic processes, in particular charging or discharging processes.

The change in resistance of the energy storage device can be determined for example depending on the change in the deviation over time by virtue of the change in the deviation over time, e.g. a quantitative value of the change over time, being multiplied by a constant or variable gain factor.

In this case, the gain factor can be chosen for example depending on an operating point of the energy storage device, wherein different gain factors can be assumed for different operating points. Said gain factors can be determined e.g. by simulation or by test bed-based determining methods. An operating point can be given for example depending on a state of charge and/or a temperature. However, the gain factor can also be constant.

In addition, the change in resistance of the energy storage device can be determined depending on the change in the deviation over time by a procedure in which a change in resistance determined at a present point in time is determined depending on a change in resistance determined at least at a previous point in time and the change in the deviation over time multiplied by the gain factor.

Moreover, the change in resistance of the energy storage device can be determined depending on the change in the deviation over time by the change in resistance being determined as division of the change in the deviation over time by the change in the measurement current over time. Such a determination of the change in resistance can be carried out, in particular, only if the change in the measurement current over time is greater than zero and the change over time takes place in a consideration time period that is shorter than a predetermined (small) time duration, for example shorter than 100 ms, shorter than 50 ms or shorter than 20 ms. Preferably, the time duration of the consideration time period is 10 ms.

The proposed method advantageously prevents static deviations between the model voltage and the measurement voltage from influencing the determination of the change in resistance. Consequently, the change in resistance is determined independently of said static deviations. This can be carried out, in particular, under the assumption that an assumed resistance is equal to the real battery internal resistance if no change in the deviation over time occurs.

Consequently, an accurate and reliable determination of the resistance of the energy storage device or of the change in resistance advantageously results, in particular independently of static deviations between model voltage and measurement voltage.

In a further embodiment, the determination of the change in resistance is carried out only if an absolute value of the change in the deviation over time is greater than a predetermined threshold value, for example greater than zero. It goes without saying that, in particular in order to minimize noise influences, threshold values that differ from zero can also be chosen.

This avoids carrying out the determination of the change in resistance permanently and thus also in cases of a deviation that is constant over time. This in turn advantageously leads to saving of computational time and computational capacity.

In one preferred embodiment, a measurement current is detected, wherein the determination of the change in resistance is carried out only if an absolute value of the change in the measurement current over time is greater than a predetermined threshold value, in particular greater than zero.

In addition, the determination of the change in resistance can be carried out only if the measurement current rises or decreases. A sign-sensitive consideration can be implemented in this case.

In particular, the determination of the change in resistance can thus be carried out only if a discharging current rises in terms of absolute value (and thus becomes smaller when considered sign-sensitively) or a charging current increases (and thus rises when considered sign-sensitively).

In this case, it can be assumed that a change in the measurement current over time also causes a change in the model voltage and the measurement voltage over time. Consequently, particularly in easily detectable operating states with changes in the measurement current over time it is possible to check whether a change in the deviation over time also takes place.

This also advantageously results in a saving of computational time and computational capacity. This also advantageously has the effect that a static sensor offset error of a current and/or voltage sensor does not lead to an erroneous determination of the change in resistance.

In a further preferred embodiment, the determination of the change in resistance is carried out only if the measurement current is a discharging current and the discharging current rises in terms of absolute value. This has already been explained above. It can be assumed that a change in a so-called charging resistance and a change in a so-called discharging resistance differ. This advantageously has the effect that only a change in resistance for the so-called discharging resistance is determined. This change in resistance is particularly important for subsequent further processing, for example for control of the energy output from the energy storage device.

It goes without saying that it is also possible, however, to carry out the determination of the change in resistance if the measurement current is a discharging current and the discharging current decreases in terms of absolute value. It is also conceivable for the determination of the change in resistance to be carried out if the measurement current is a charging current and the charging current rises or decreases in terms of absolute value.

In a further embodiment, the change in resistance is determined at a plurality of successive points in time, wherein the change in resistance at a present point in time is determined depending on the change in resistance at least one previous point in time. In particular, the change in resistance can be determined recursively.

By way of example, the change in resistance at a present point in time can be determined depending on the change in resistance at least one previous point in time by a procedure in which the product of gain factor and the change in the deviation over time is added to the change in resistance which was determined at the directly preceding point in time.

This results in an integration of the change in resistance. This in turn advantageously necessitates that preceding changes in resistance are also taken into account. In addition, the advantage is also afforded that slight calculation errors at individual calculation points in time have less of an effect on the overall result.

In one preferred embodiment, the change in resistance at the present point in time is determined as a manipulated variable of a control specification, wherein the change over time in the deviation between the model voltage and the measurement voltage corresponds to the reference variable of the control specification. The control specification can be, in particular, a control specification corresponding to the control specification of an I controller. This advantageously results in a determination of the change in resistance that is as accurate as possible.

In a further embodiment, the change in the deviation over time and the change in the measurement current over time are filtered. In particular, the change in the deviation over time and the change in the measurement current over time can be filtered by means of the same filter specification. This advantageously has the effect that the filtering does not result in a phase shift between the change in the deviation over time and the change in the measurement current over time.

Preferably, a low-pass filtering of the change in the deviation over time and of the change in the measurement current over time is carried out. In this case, the low-pass filtering of the change in the deviation over time and of the change in the measurement current over time can have identical time constants, for example time constants of 0.5 s, and/or identical gains.

This advantageously has the result that harmonics do not influence or only insignificantly influence and thus corrupt the determination of the change in resistance.

In a further embodiment, a correction voltage for the model voltage is determined depending on the deviation between the model voltage and the measurement voltage. By way of example, the model voltage determined at a present point in time can then additionally be determined depending on the correction voltage determined at a previous point in time, in particular the correction voltage determined at the directly preceding point in time.

The model voltage corrected in this way can then in turn be used at the present point in time for determining the change in resistance. In addition, it is possible that the model voltage corrected in this way can also be used for further open-loop and closed-loop control processes in the vehicle, for example for controlling the power output and/or for predicting an available power.

Furthermore, it is conceivable to assign proportions of the correction voltage to individual elements of the model for determining the model voltage. By way of example, it is thus possible to determine correction factors for inaccurate OCV (open circuit voltage) families of characteristic curves.

In a further embodiment, the correction voltage is determined as a manipulated variable of a control specification, wherein the deviation between the model voltage and the measurement voltage corresponds to the reference variable of the control specification. The control specification can be, in particular, a control specification of an I controller or of a PI controller. This advantageously results in a determination of the correction voltage that is as accurate and reliable as possible.

In a further embodiment, the model voltage is determined depending on a present resistance of the energy storage device and depending on at least one operating parameter, preferably depending on a state of charge, a temperature and a charging or discharging current, of the energy storage device.

In this case, the present resistance can represent a model parameter of the model. Further model parameters can be, for example, time constants that characterize dynamic voltage changes in the output voltage of the energy storage device.

In particular, the model voltage can be determined as a sum of an OCV voltage, an ohmic voltage, a first dynamic voltage proportion and a further dynamic voltage proportion.

In this case, the OCV voltage can be determined in an operating point-dependent manner, in particular depending on a state of charge and a temperature of the energy storage device. The OCV voltage can be determined by means of a previously known relationship between the operating point or operating parameters of said operating point and the OCV voltage. The previously known relationship can be given in particular in the form of a family of characteristic curves or in the form of a previously known functional assignment. The previously known relationship can be determined e.g. by means of suitable simulations or, in particular test bed-based, determining methods.

The ohmic voltage drop can be determined depending on the state of charge, the temperature and the charging or discharging current. The ohmic voltage drop can model a voltage drop across the resistance of the energy storage device. Said resistance can be determined, in particular at the beginning of the determination of the change in resistance, likewise in an operating point-dependent manner, in particular depending on a state of charge and a temperature of the energy storage device. In this case, the resistance can correspond to the initial resistance explained above.

The resistance can likewise be determined by means of a previously known relationship between the operating point or operating parameters of said operating point and the resistance. For this purpose, the previously known relationship can be given in particular in the form of a family of characteristic curves or in the form of a previously known functional assignment. The previously known relationship can be determined e.g. by means of suitable simulations or, in particular test bed-based, determining methods.

The present resistance of the energy storage device can then be determined in particular as a sum of the initial resistance or of the resistance determined at a previous point in time and the change in resistance.

The first and further dynamic voltage proportions can be determined depending on the state of charge, the temperature, the charging or discharging current and the time constants explained above, wherein the time constants for determining the first and further dynamic voltage proportions differ from one another.

This advantageously results in a determination of the model voltage that is as accurate as possible.

Also proposed is an apparatus for determining a change in resistance of an energy storage device. The apparatus comprises at least one device for detecting a measurement voltage of the energy storage device, for example a voltage sensor. Furthermore, the apparatus can comprise at least one device for detecting a measurement current of the energy storage device, in particular a current sensor. Furthermore, the apparatus comprises at least one evaluation device for determining a model voltage of the energy storage device.

According to the invention, a change in the deviation over time is determinable, in particular by the evaluation device, wherein the change in resistance of the energy storage device is determinable depending on the change in the deviation over time.

Furthermore, the apparatus can also comprise a memory device for storing different variables, in particular a change in resistance determined at a previous point in time.

In this case, the apparatus is embodied in particular in such a way that a method according to any of the embodiments explained above can be carried out by means of the apparatus.

Also proposed is a vehicle comprising an apparatus according to the embodiments described above. In this case, the vehicle can be in particular an electric vehicle or hybrid vehicle. In this case, the vehicle can comprise the at least one energy storage device.

### BRIEF DESCRIPTION OF THE DRAWINGS

The invention is explained in greater detail on the basis of an exemplary embodiment. In the figures:

FIG. 1 shows a schematic block diagram of an apparatus according to the invention,

FIG. 2 shows a schematic block diagram of a method according to the invention,

FIG. 3 shows a first exemplary time profile of a measurement voltage, of a model voltage, of a deviation and of a measurement current, and

FIG. 4 shows a further exemplary temporal profile of a measurement voltage, of a model voltage, of a deviation and of a measurement current.

### DETAILED DESCRIPTION OF THE INVENTION

Hereinafter, identical reference signs denote elements having identical or similar technical features.

FIG. 1 illustrates a schematic block diagram of an apparatus 1 according to the invention, which can be part of a vehicle (not illustrated). An energy storage device 2 is illustrated, which can be for example a battery cell of a traction battery.

The apparatus 1 comprises a current sensor 3 for detecting a measurement current I, which denotes a charging or discharging current. Furthermore, the apparatus 1 comprises a voltage sensor 4 for detecting a measurement voltage Umeas, wherein the measurement voltage Umeas constitutes an output voltage of the energy storage device 2. Furthermore, the apparatus 1 comprises a temperature sensor 5 for detecting an operating temperature of the energy storage device 2. Furthermore, the apparatus 1 comprises an evaluation device 6. The evaluation device 6 is connected to the temperature sensor 5, the voltage sensor 4 and the current sensor 3 data-and/or signal-technologically, which is illustrated by dashed lines. The method explained below can be carried out by means of the evaluation device 6.

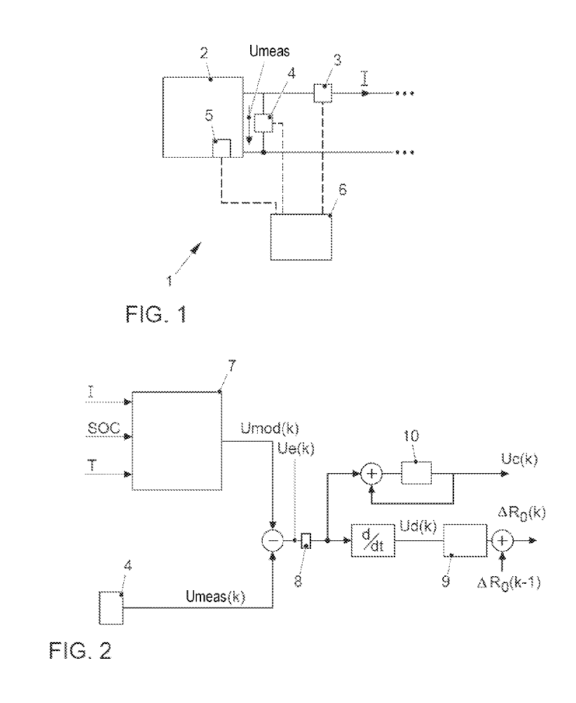

FIG. 2 illustrates a schematic block diagram of a method according to the invention. A block represents a model 7 for determining a model voltage Umod(k), where k denotes a present point in time. In this case, input variables of the model 7 are the measurement current I (see FIG. 1), a state of charge SOC of the energy storage device 2 and the temperature T of the energy storage device 2, which can be detected for example by the temperature sensor 5 (see FIG. 1). In this case, the state of charge SOC can be determined by means of methods known to the person skilled in the art. By way of example, the state of charge SOC can be determined proceeding from a known state of charge, for example a state of charge of 1.0, by means of an evaluation, e.g. integration, of a detected charging and discharging current I over a time duration since the last determination point in time of the state of charge SOC.

By way of example, the evaluation device 6 (see FIG. 1) can calculate the model voltage Umod(k) depending on the model 7. In this case, the model used can be described as follows:

Umod(k)=U_{OCV}(SOC(k), T(k))+U₀(SOC(k), T(k), I(k))+U₁(SOC(k), T(k), I(k), t1)+U₂(SOC(k), T(k), I(k), t2) Formula 1

wherein U_{OCV} denotes an open circuit voltage, U₀ denotes an ohmic voltage drop across a resistance of the energy storage device 2, U₁ denotes a first dynamic voltage proportion of the output voltage, and U₂ denotes a further dynamic voltage proportion of the output voltage. The dynamic voltage proportions U₁, U₂ in this case model dynamic changes in voltage during charging or discharging processes.

The open circuit voltage U_{OCV} is dependent on the state of charge SOC and the temperature T at the point in time k. This dependence can be modeled in particular in the form of a two-dimensional family of characteristic curves which is parameterized prior to the start-up of the energy storage device 2. For this purpose, by way of example, a so-called OCV parameterization test can be carried out on a cell test bed for a battery cell. In this case, at predetermined states of charge SOC and at specific temperatures T, the open circuit voltage U_{OCV} can be determined and stored in the two-dimensional family of characteristic curves, wherein an open circuit voltage U_{OCV} is assigned to each operating point (SOC, T).

The family of characteristic curves formed in this way can then e.g. also serve for determining an open circuit voltage family of characteristic curves of a battery consisting of a plurality of battery cells of identical type. For this purpose, the family of characteristic curves determined for a battery cell can be converted depending on the interconnection of the battery cells in the battery.

The ohmic voltage drop U₀ can be calculated as follows:

U₀(k)=R₀(R_{KF}(SOC(k), T(k)), ΔR₀)×I(k) Formula 2

wherein it holds true that

R₀=R_{KF}(SOC(k), T(k))+ΔR₀ Formula 3

In this case, R_{KF} denotes an initial resistance value which, in a manner corresponding to the open circuit voltage U_{OCV}, is dependent on the state of charge SOC and the temperature T. This initial resistance R_{KF} can also be modeled in the form of a two-dimensional family of characteristic curves. In this case, the initial resistance R_{KF} for a charging process and a discharging process can be determined separately, as a result of which e.g. a family of characteristic curves for determining the initial resistance R_{KF} for a charging process and a further family of characteristic curves for determining the initial resistance R_{KF} for a discharging process are determined. These families of characteristic curves can also be parameterized by means of suitable methods.

The change in resistance ΔR₀ denotes the deviation of the resistance of the energy storage device 2 at the present point in time with respect to the initial resistance R_{KF}.

The first dynamic voltage drop U₁ can be determined as follows:

U₁(k)=(1−exp(−T_{S}/t1))×U₁(k−1)+R₁×exp(−T_{S}/t1)×I(k) Formula 4

wherein T_{S} denotes a sampling time duration, t1 denotes a time constant of a first RC element, and R₁ denotes a gain of said first RC element. In this case, the index k denotes a present point in time, wherein the index k−1 denotes the directly preceding (discrete) point in time.

The second dynamic voltage drop U₂ is determined in accordance with Formula 4, wherein, however, the time constant t1 is replaced by the time constant t2 and the gain factor R₁ is replaced by the gain factor R₂.

Both the time constants t1, t2 and the gain factors R₁, R₂ can be dependent on the temperature T and on the state of charge SOC. By way of example, the time constants t1, t2 and also the gain factors R₁, R₂, as explained above, can be modeled in each case in the form of two-dimensional families of characteristic curves, wherein the families of characteristic curves respectively assign a time constant and a gain to each operating point (OCV, T).

Consequently, all the families of characteristic curves explained above can be determined by known parameterization methods prior to the start-up of the energy storage device. By way of example, the initial resistance R₁, the gain factors R₁, R₂ and the time constants t1, t2 can be determined in such a way that a deviation between a modeled voltage Umod and a measurement voltage Umeas is minimized. In this case, said parameterization methods can be carried out both at the cell level and at the battery level. If the parameterization methods have been carried out at the cell level, then the families of characteristic curves can be determined for a battery by a corresponding conversion depending on the electrical interconnection of the battery cells in the battery.

FIG. 2 furthermore illustrates that the measurement voltage Umeas(k) is detected by means of the voltage sensor 4 (see FIG. 1). The figure furthermore illustrates that a deviation between the model voltage Umod and the measurement voltage Umeas is determined as the difference

Ue(k)=Umod(k)−Umeas(k) Formula 5

In this case, the deviation Ue is determined at each (sampling) point in time k.

The figure furthermore illustrates that the deviation Ue(k) or a temporal profile of the deviation Ue(k) is low-pass-filtered by means of a filter device 8, in order e.g. to reduce harmonics governed by power electronics in the measurement voltage Umeas. The filtered deviation results as

Ue,filt(k)=kfilt×Ue(k)+(1−kfilt)×Ue,filt(k−1) Formula 6

The transfer function of such a filtering in the Laplace domain is given by f(p)=1/(Tp+s), wherein T denotes the time constant and can be 0.5 s, for example.

In this case, the measurement current I can also be filtered in the same way in order to achieve an identical phase shift between the filtered deviation Ue,filt and the (filtered) measurement current I.

After the filtering, which is preferably, but not necessarily, to be provided, a change in the deviation Ue over time is determined. This can be given for example as follows:

Ud(k)=Ue(k)−Ue(k−1) Formula 7

In this case, Ud denotes the change over time in the deviation Ue between two successive (sampling) points in time k.

In this case, it can be assumed that the difference Ud(k) is zero if the resistance R₀ used in the model 7 is equal to the real resistance of the energy storage device 2. For this purpose, it can be assumed, for example, that in a predetermined (short) calculation time period a difference between a real open circuit voltage and an open circuit voltage determined in a model-based manner and also a difference between a real first dynamic voltage proportion of the output voltage and a first dynamic voltage proportion of the output voltage that is determined in a model-based manner, and also a difference between a real second dynamic voltage proportion of the output voltage and a second dynamic voltage proportion of the output voltage that is determined in a model-based manner are zero or approximately zero independently of a deviation between the real resistance and the resistance R₀ used in the model 7. Consequently, only a difference between a real ohmic voltage drop across a resistance of the energy storage device 2 and an ohmic voltage drop across the resistance of the energy storage device 2 that is determined in a model-based manner is not equal to zero if the resistance R₀ used in the model 7 is not equal to the real resistance of the energy storage device 2, and is equal to zero if the resistance R₀ used in the model 7 is equal to the real resistance of the energy storage device 2.

The change Ud(k) in the deviation Ue over time can then be amplified by an amplifier device 9 with a gain factor kd. The change in resistance ΔR₀(k) at the present point in time k can then be determined as a sum of the amplified change Ud(k) and the change in resistance ΔR₀(k−1) determined at the directly preceding point in time k−1

ΔR₀(k)=ΔR₀(k−1)+kd×Ud(k) Formula 8

In this case, the gain factor kd can be predetermined and constant.

A present resistance R₀(k) of the energy storage device 2 can then be determined as a sum of the above-explained initial resistance R_{KF} and the change in resistance ΔR₀(k) determined.

Preferably, the described determination of the change in resistance ΔR₀(k) is carried out only if the measurement current I or the filtered measurement current has a falling edge and is a discharging current. This, too, can be based on the above-explained assumption that in a predetermined calculation time period, for example a time period of shorter than 100 ms, shorter than 50 ms or shorter than 20 ms, only a difference between a real ohmic voltage drop across a resistance of the energy storage device 2 and an ohmic voltage drop across the resistance of the energy storage device 2 that is determined in a model-based manner is not equal to zero if the resistance R₀ used in the model 7 is not equal to the real resistance of the energy storage device 2, and is equal to zero if the resistance R₀ used in the model 7 is equal to the real resistance of the energy storage device 2. The remaining differences between the real voltage and the voltage determined in a model-based manner can be assumed to be zero or approximately zero independently of a deviation between the real resistance and the resistance used in the model 7 in the calculation time period.

The figure furthermore illustrates that the deviation Ue(k) or filtered deviation Ue(k) serves as a reference variable for a control device 10, wherein a correction voltage Uc(k) can be determined as a manipulated variable by means of the control device 10. The control device 10 can be embodied as an I controller or PI controller, for example. By means of the correction voltage Uc(k), for example, the model voltage Umod(k+1) determined at a subsequent point in time k+1 can be corrected, for example by summation of the model voltage Umod(k+1) determined by means of the model 7 and the correction voltage Uc(k).

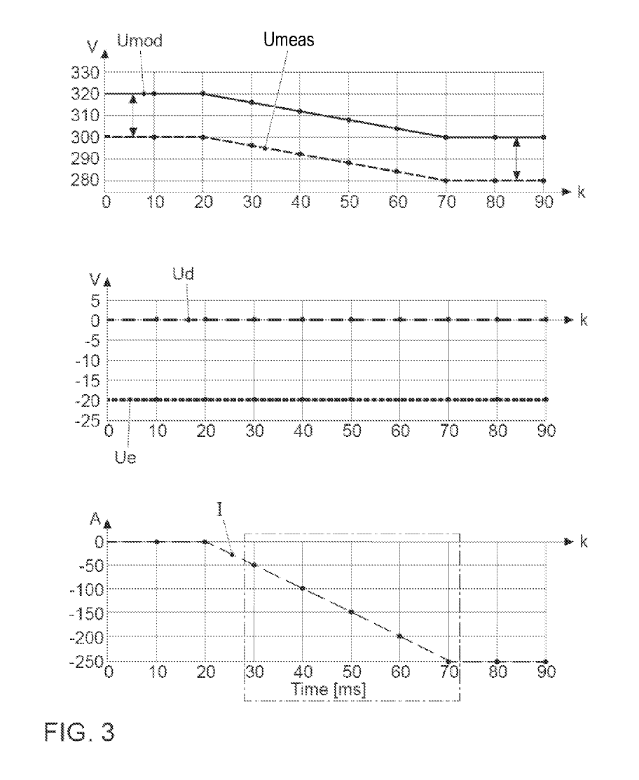

FIG. 3 illustrates exemplary time profiles of the model voltage Umod, of the measurement voltage Umeas, of the deviation Ue, of the change Ud in the deviation Ue over time, and of the measurement current I. In this case, the time profile is plotted on the abscissa, wherein k denotes successive sampling points in time.

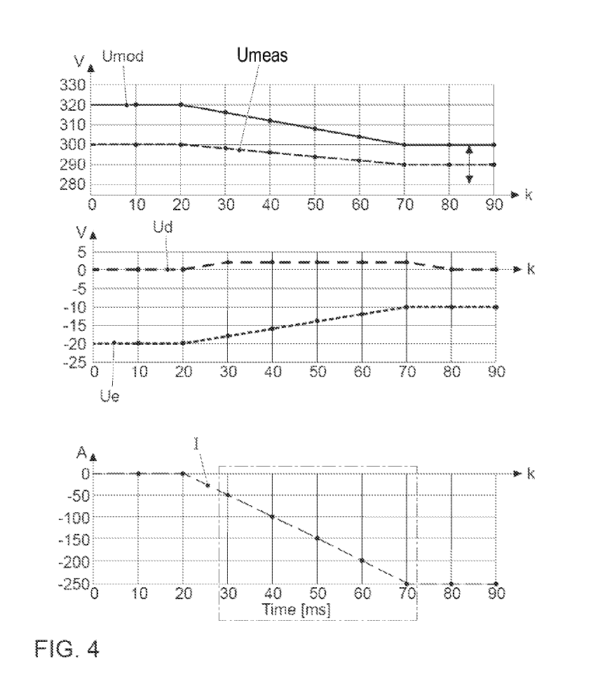

The topmost line in FIG. 3 illustrates a time profile of the model voltage Umod and of the measurement voltage Umeas, wherein the voltages Umod, Umeas are indicated in volts V. Starting from a point in time k=20, both the model voltage Umod and the measurement voltage Umeas fall, but the deviation Ue between model voltage Umod and measurement voltage Umeas, which is determined as a difference between the measurement voltage Umeas and the model voltage Umod in FIG. 3 and FIG. 4, remains constant. Consequently, the change Ud in said deviation Ue over time is zero (see second line in FIG. 3).

The third line in FIG. 3 illustrates a corresponding profile of the measurement current I.

A dash-dotted line illustrates a time window in which the measurement current I has a falling edge. In the exemplary embodiment illustrated, a discharging current increases in terms of absolute value, which leads to an increasing discharge of the energy storage device 2.

In this case, the determination of the change in resistance ΔR₀(k) is carried out only in said time window. Since the change Ud in the deviation Ue over time is zero in said time window, a change in resistance ΔR₀(k) of zero is determined.

FIG. 4 illustrates a further exemplary profile of a model voltage Umod, of a measurement voltage Umeas, of a deviation Ue and of a change Ud in the deviation Ue over time, and also a temporal profile of a measurement current I. In contrast to the temporal profiles illustrated in FIG. 3, the model voltage Umod falls to a greater extent than the measurement voltage Umeas in the time interval identified by the dash-dotted line. The deviation Ue between the model voltage Umod and the measurement voltage Umeas thus decreases. The change Ud over time thus differs from zero and assumes a positive value, in particular. The change in resistance ΔR₀(k) determined in this time interval thus differs from zero.

### LIST OF REFERENCE SIGNS

1 Apparatus
2 Energy storage device
3 Current sensor
4 Voltage sensor
5 Temperature sensor
6 Evaluation device
7 Model
8 Filter device
9 Amplifier device
10 Controller device
I Measurement current
Umeas Measurement voltage
Umod Model voltage
SOC State of charge
T Temperature
k Point in time
k−1 Previous point in time
Ue Deviation
Ud Change over time
Uc Correction voltage
ΔR₀ Change in resistance
V Volt
A Ampere

Having described the invention, the following is claimed:

1. Method for determining a change in resistance (ΔR₀) of an energy storage device, the method comprising:
detecting a measurement voltage (Umeas) of the energy storage device,
determining a model voltage (Umod) of the energy storage device,
determining a deviation (Ue) between the model voltage (Umod) and the
measurement voltage (Umeas), and
determining a change (Ud) in the deviation (Ue) over time,
wherein the change in resistance (ΔR₀) of the energy storage device is determined depending on the change (Ud) in the deviation (Ue) over time.

2. Method according to claim 1, wherein the determination of the change in resistance (ΔR₀) is carried out only if an absolute value of the change (Ud) in the deviation (Ue) over time is greater than a predetermined threshold value.

3. Method according to claim 1, wherein the method further comprises:
detecting a measurement current (I), wherein the determination of the change in resistance (ΔR₀) is carried out only if an absolute value of the change in the measurement current (I) over time is greater than a predetermined threshold value.

4. Method according to claim 3, wherein the determination of the change in resistance (ΔR₀) is carried out only if the measurement current (I) is a discharging current and the discharging current rises in terms of absolute value.

5. Method according to claim 1, wherein the change in resistance (ΔR₀) is determined at a plurality of successive points in time (k−1, k), wherein the change in resistance (ΔR₀) at a present point in time (k) is determined depending on the change in resistance (ΔR₀) at least one previous point in time (k−1).

6. Method according to claim 5, wherein the change in resistance (ΔR₀) at the present point in time (k) is determined as a manipulated variable of a control specification, wherein the change (Ud) over time in the deviation (Ue) between the model voltage (Umod) and the measurement voltage (Umeas) corresponds to a reference variable of a control specification.

7. Method according to claim 3, wherein the method further comprises:
filtering the change (Ud) in the deviation (Ue) over time and filtering the change in the measurement current (I) over time.

8. Method according to claim 1, wherein the method further comprises:
determining a correction voltage (Uc) for the model voltage (Umod) depending on the deviation (Ue) between the model voltage (Umod) and the measurement voltage (Umeas).

9. Method according to claim 8, wherein the correction voltage (Uc) is determined as a manipulated variable of a control specification, wherein the deviation (Ue) between the model voltage (Umod) and the measurement voltage (Umeas) corresponds to a reference variable of the control specification.

10. Method according to claim 1, wherein the model voltage (Umod) is determined depending on a present resistance (R₀) of the energy storage device and depending on at least one operating parameter of the energy storage device.

11. Apparatus for determining a change in resistance (ΔR₀) of an energy storage device, wherein the apparatus comprises:
at least one device for detecting a measurement voltage (Umeas) of the energy storage device, and
at least one evaluation device for determining a model voltage (Umod) of the energy storage device, wherein a change (Ud) in a deviation (Ue) between the model voltage (Umod) and the measurement voltage (Umeas) is determined, the change in resistance (ΔR₀) of the energy storage device is determinable depending on the change (Ud) in the deviation (Ue) over time.

12. A vehicle comprising:
an apparatus for determining a change in resistance (ΔR₀) of an energy storage device, wherein the apparatus comprises:
at least one device for detecting a measurement voltage (Umeas) of the energy storage device, and
at least one evaluation device for determining a model voltage (Umod) of the energy storage device,
wherein a change (Ud) in a deviation (Ue) between the model voltage (Umod) and the measurement voltage (Umeas) is determined, the change in resistance (ΔR₀) of the energy storage device is determinable depending on the change (Ud) in the deviation (Ue) over time.
